(19) United States
(12) Patent Application Publication
(10) Pub. No.: US 2020/0200798 A1
(43) Pub. Date: Jun. 25, 2020

(54) TOUCHLESS PROBE CARD CLEANING APPARATUS AND METHOD

(71) Applicant: Texas Instruments Incorporated, Dallas, TX (US)

(72) Inventors: Lorence Sy Pareja, Garland, TX (US); Hector Hugo Moreno, Richarson, TX (US); Broderick Schaun Parks, JR., Irving, TX (US)

(21) Appl. No.: 16/229,357

(22) Filed: Dec. 21, 2018

(51) Int. Cl. G01R 1/073; G01R 1/067; G01R 1/04

(52) U.S. Cl. CPC G01R 1/07342; G01R 1/04; G01R 1/07364; G01R 1/06733

(57) ABSTRACT

Automatic probe card cleaning apparatus includes a vacuum pump connected to draw air through an exhaust nozzle, an ionizer with connected to direct a stream of ionized air through an output nozzle, and a support structure that supports the nozzles proximate a probe needle of a probe card, the support structure movable between a first cleaning position and a second position that allows the probe needle to contact a wafer for testing.

### BACKGROUND

Wafer probe testing is used in semiconductor device manufacturing to test circuit die portions of a fabricated wafer to verify circuit quality prior to die singulation. Common probe testing includes tests for short circuit and open circuit faults. A probe tester includes straight or cantilevered probe needles or pins mounted to a probe card and supported on a probe head. The tested wafer is mounted to a chuck and the probe head and chuck are brought together to engage the probe needles with aluminum or copper pads, solder bumps, or other conductive features of the wafer. Good electrical connection between the wafer pads and the probe needles is important for accurate quality assessment during probe testing. During testing, debris from the probed wafers can accumulate on or between the probe needles. As an example, probing the conductive features of the wafer often includes scrubbing metal pads to break through oxidation to establish good continuity. The scrubbing action can generate debris and other particles that may adhere to the probe needles. Dirty probe needles can lead to false positives or false negatives during wafer probe testing, both of which are expensive in terms of product yield and manufacturing costs. The probe needles can be cleaned or scrubbed using abrasive cleaning pads or brushes. However, small fine pitch needles for testing modern circuits are fragile, and the cleaning pads can be actuated only in a direction of the needles to avoid needle damage during cleaning. The resulting cleaning is often incomplete, with the debris often becoming packed more tightly between needles by the pad motion or needle misalignment/damage by brush cleaning. Moreover, cleaning with pads or brushes wears the contact surfaces of the probe needles, and thus reduces the useful life of the probe card.

### SUMMARY

Described example apparatus includes a vacuum pump with an output connected to draw air through an exhaust nozzle, and an ionizer with an output connected to direct a stream of ionized air through an output nozzle. A support structure has a first position that supports the exhaust nozzle and the output nozzle proximate a probe needle of a probe card. In one example, the support structure is movable to a second position that allows the probe needle to contact a wafer for testing. In one example, a controller automatically positions the support structure in the first position to locate the output nozzle to direct the stream of ionized air toward the probe needle of the probe card, and to locate the exhaust nozzle to draw air and dislodged debris away from the probe needle of the probe card. In one example, the controller operates a valve to cause the ionizer to direct a pulsed stream of ionized air toward the probe needle. The apparatus in one example also includes a pressure regulator connected between an air supply and the ionizer to control a peak pressure of the stream of ionized air directed toward the probe needle.

An example method includes positioning a support structure with exhaust and output nozzles proximate a probe needle of a probe card, directing a stream of ionized air through the output nozzle toward the probe card to dislodge debris from the probe needle of the probe card, and drawing air and the dislodged debris away from the probe card through the exhaust nozzle while directing the stream of ionized air toward the probe card.

### BRIEF DESCRIPTION OF THE DRAWINGS

FIG. 1 is a simplified side elevation view of a wafer probe test system operating in a first mode with a touchless automatic cleaning apparatus proximate a probe card.

FIG. 2 is a flow diagram of a method to clean a probe card in a wafer probe test system.

FIG. 3 is a simplified side elevation view of the wafer probe test system operating in a second mode with probe needles of the probe card contacting a wafer being tested.

### DETAILED DESCRIPTION

In the drawings, like reference numerals refer to like elements throughout, and the various features are not necessarily drawn to scale. In the following discussion and in the claims, the terms “including”, “includes”, “having”, “has”, “with”, or variants thereof are intended to be inclusive in a manner similar to the term “comprising”, and thus should be interpreted to mean “including, but not limited to . . . ” Also, the term “couple” or “couples” is intended to include indirect or direct electrical or mechanical connection or combinations thereof. For example, if a first device couples to or is coupled with a second device, that connection may be through a direct electrical connection, or through an indirect electrical connection via one or more intervening devices and connections.

Example test apparatus and methods provide automatic touchless probe needle cleaning using an ionized air stream directed toward a probe card and a vacuum to draw air and debris away from the probe card. The disclosed examples facilitate automated needle cleaning without damage and wear associated with scrubbing pads or brushes, and without requiring changes to the probe system setup. Using ionized air facilitates discharging debris to help dislodge particles from the probe card surface and from the probe needles, and also helps reduce electrostatic discharge on the needles.

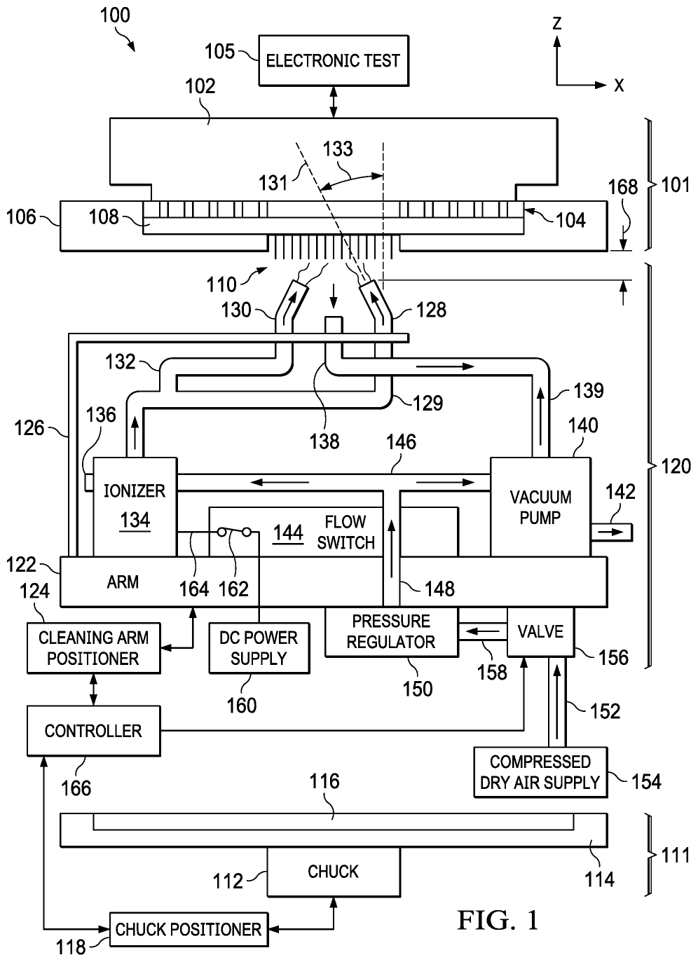

FIG. 1 shows an automated wafer probe test system or prober 100. The system 100 is shown in a first mode (CLEAN) for cleaning probe head needles. The system 100 is operable in a second mode (TEST) for testing a wafer. The system 100 includes a probe head assembly 101 with a test head 102. The test head 102 includes conductive connections 104, such as pogo pins, that are electrically connected to an electronic test circuit 105. The conductive connections 104 extend into a recess in a head plate 106. As an example, the test head 102 and the head plate 106 can be ceramic material. The probe head assembly 101 also includes a probe card 108 seated in the head plate recess. The probe card 108 includes top side pads electrically connected to the pogo pin conductive connections 104 of the test head 102. The probe card 108 includes probe needles 110 that extend downward (e.g., along the −Z direction in FIG. 1) through an opening in the bottom of the head plate 106 to contact a wafer under test in one operating mode of the system 100. The electronic test circuit 105 in one example is configured to implement electrical testing of a probed wafer, such as tests for short circuit and open circuit faults and/or other operational functional tests.

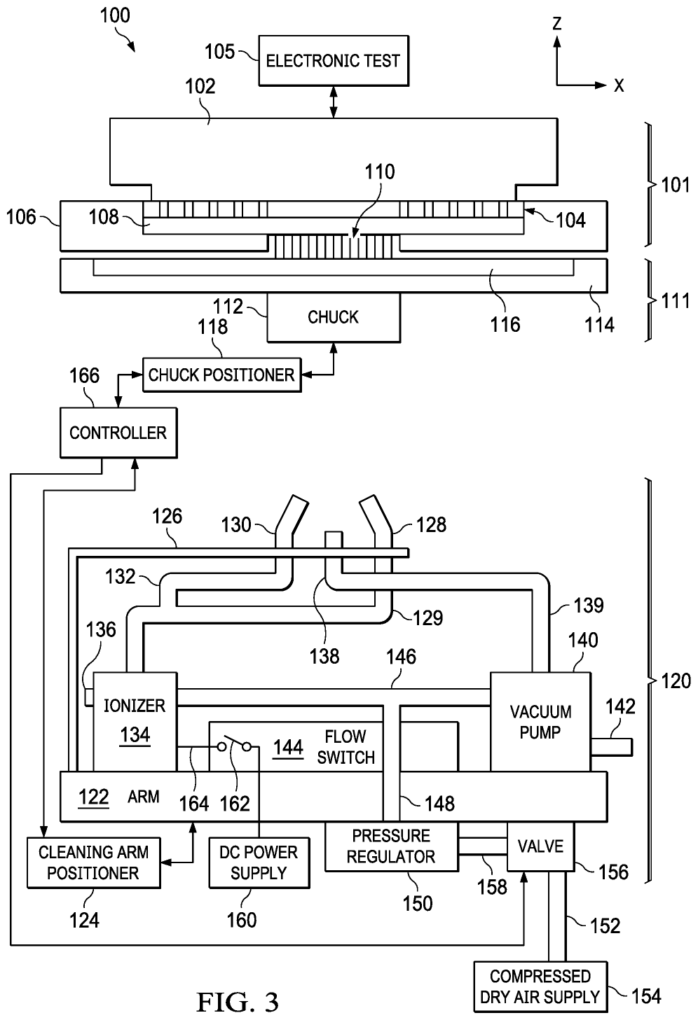

The system 100 also includes a chuck apparatus 111 with a chuck 112 and an attached carrier 114 configured to support a wafer 116. The chuck 112 is mechanically supported and positioned by an attached chuck positioner apparatus 118. The chuck positioner apparatus 118 is configured to move or otherwise translate the chuck apparatus 111 between a first chuck position shown in FIG. 1 that allows the probe needles 110 to be cleaned in the first operating mode, and a second chuck position that contacts the wafer 116 with the probe needles 110 in the second operating mode described below in connection with FIG. 3. As an example, the chuck positioner apparatus 118 can include linear or rotary servos, positioner actuators and mechanical supporting structures to move the chuck 112, along with the associated carrier 114 and an installed wafer 116, to any position and orientation in a three dimensional space relative to the position of the probe head assembly 101 and the probe needles 110 thereof.

The wafer probe test system 100 also includes a touchless cleaning apparatus 120. The cleaning apparatus 120 includes a base or arm structure 122 connected to a cleaning arm positioner apparatus 124. The arm 122 is mounted to a cleaning apparatus support structure 126. The positioner apparatus 124 is configured to move the support structure 126 between a first support structure position shown in FIG. 1 for cleaning during the first operational mode, and a second support structure position that allows the probe needles 110 to contact a wafer 116 for testing in the second operating mode described below in connection with FIG. 3. As an example, the cleaning arm positioner apparatus 124 can include linear or rotary servos and positioner actuators and mechanical supporting structures to move the arm structure 122 along with associated carrier 114 and an installed wafer 116 to any position and orientation and a three dimensional space relative to the position of the probe head assembly 101 and the probe needles 110 thereof.

In one implementation, the positioners 118 and 124 each include linear actuators and associated servo controls to translate the respective apparatus 111 and 120 up and down along the Z axis shown in FIG. 1, as well as X-Y controls for lateral positioning of the apparatus 111 and 120 within the system 100 relative to the position of the probe head assembly 101. In one example, one or both of the positioners 118 and/or 124 include rotational actuators and associated servo controls to change angles of the respective movable apparatus 111 and 124 at non-zero angles relative to one of the X, Y and/or Z directions. The positioner apparatus 118 and 124 in one example are equipped with corresponding electronic processors an associated electronic memory (not shown), and are programmed and/or programmable with program instructions stored in the respective memories to implement three-dimensional and angular positioning functions by execution of the stored instructions by the respective processor components. In one example, the positioner apparatus 118 and 124 include communications interfaces to communicate with external control devices, such as a system controller described below. In one example, the positioner apparatus 118 and 124 are configured to receive operating messages and/or instructions from an external controller to operate the positioners to move the associated chuck apparatus 111 and the cleaning support structure 122, 126 to implement first and second operating modes to clean the probe needles 110 and to test a wafer 116, respectively.

The support structure 126 supports an exhaust nozzle 138 that draws air and debris away from the probe card 108 and the probe needles 110 when the support structure 126 is in the first support structure position as shown in FIG. 1. In addition, output nozzles 128 and 130 are provided as outputs to direct ionized air toward the probe needles 110 and the associated probe card 108 in the first support structure position. FIG. 1 shows an example, in which an output nozzle 128 and a second output nozzle 130 are positioned on either side of the exhaust nozzle 138 to direct ionized air toward the probe card 108 and the probe needles 110. In another example, a single output nozzle can be used (e.g., nozzle 128). In other implementations, more than two output nozzles can be used. In the illustrated example, the output nozzles 128 and 130 are laterally, outwardly spaced from a centrally located exhaust nozzle 138. In other implementations, a centrally located output nozzle can be used, with one or more laterally outwardly spaced (and angled) exhaust nozzles (not shown). A variety of different relative positions can be used for one or more exhaust nozzles and one or more output nozzles in different implementations.

The nozzles 138, 128 and 130 in this example are mounted to the support structure 126 by extension through corresponding holes in the structure 126. The output nozzle 128 is connected to an output hose (e.g., a tube) 129, the second output nozzle 130 is connected to a second output hose 132, and the exhaust nozzle 138 is connected to an exhaust hose (e.g., a tube) 139 as schematically shown in FIG. 1. The arm 122 in the illustrated example supports an ionizer 134 with an output connected to the output hoses 129 and 132. When the ionizer 134 is powered, the output provides a pressurized stream of ionized air through the output hoses 129 and 132 and the respective output nozzles 128 and 130, which direct respective streams of ionized air toward one or more of the probe needles 110. The ionizer 134 in one example includes a sensor 136 that senses the ambient air surrounding the apparatus 120. In operation, the ionizer 134 adds positive or negative ions to the pressurized air output stream according to the ionization level detected by the sensor 136.

The ionizer 134 and the tubes 129, 132 and nozzles 128, 130 direct ions toward the probe needles 110 and the probe card 108 to discharge the probe card and needles 108 and 110 through closed-loop ionization polarity and level control. In practice, particulate matter attached to the probe card 108 and/or the probe needles 110 through charged attraction or magnetic attraction will be at least partially discharge by the directed ionized airstream from the nozzles 128 and 130 to enhance the detachment of debris. In this manner, the debris of the probe card 108 and/or the probe needles 110 is deionized and discharged, leading to debris falling via gravitational force as well as through the force of the directed air from the nozzles 128 and 130 and the vacuum from the exhaust nozzle 138. The deionization of the probe card 108 and the needles 110 also reduces buildup charges to mitigate or eliminate electrostatic discharge between the probe card 108, the needles 110 and a tested wafer 116 during operation in the test mode. The touchless cleaning provided by the cleaning apparatus 120 provides significant advantages with respect to electrostatic discharge minimization compared with scrubbing pads or brushes.

The arm 122 in the example of FIG. 1 also supports a vacuum pump 140 with an output connected to draw air and dislodged debris through the exhaust nozzle 138 and away from the probe card 108 and the probe needles 110. The pump 140 includes an outlet or exhaust pipe 142 that discharges pumped air to the ambient of the cleaning apparatus 120. In one example, the cleaning apparatus 120 also includes a flow switch 144 with an outlet 146 that directs air into an input of the vacuum pump 140 as well as an input to the ionizer 134. The flow switch 144 includes an input 148 connected to an output or outlet of a pressure regulator 150. In the illustrated example, the arm structure 122 supports the ionizer 134, the vacuum pump 140, the flow switch 144 and the pressure regulator 150, although not a strict requirement of all possible implementations. In other examples, one or more of the devices 134, 140, 144 and/or 150 can be separately supported elsewhere within the system 100. Mounting the ionizer 134 and the ambient sensor 136 close to the nozzles 128, 130, 138 facilitates closed-loop control of the ionization level and discharging of the probe card 108 and the probe needles 110. The ionizer 134 and the vacuum pump 140 in this example operate from compressed dry air provided through an outlet or output tube or pipe 152 from a compressed dry air (CDA) supply 154. In one example, the pressure regulator 150 controls a peak pressure of the stream of ionized air directed toward the probe card 108 and the probe needles 110 to be 5 pounds per square inch (PSI) or more and 30 PSI or less.

The example cleaning apparatus 120 further includes a valve 156 mounted to the support structure arm 122. The valve 156 receives compressed air from the output tube 152 of the compressed dry air supply 154. The valve 156 includes an outlet or output 158 connected to selectively provide air from the supply 154 to an input of the pressure regulator 150. The valve 156 includes a control input to receive an electrical signal to selectively open or close the valve. In one example, the valve 156 is dynamically operated during the first operational mode to selectively provide a pulsed airstream to the pressure regulator 150 and downstream devices including the flow switch 144, the vacuum pump 140 and the ionizer 134. This example allows the outlet nozzles 128 and/or 130 to direct a pulsed stream of ionized air toward the probe card 108 and the probe needles 110.

The cleaning apparatus 120 in FIG. 1 also includes a DC power supply 160 (e.g., 24 V DC) connected through an electrical switch 162 of the flow switch 144 to a power input 164 of the ionizer 134. The electrical switch 162 is configured to connect the power supply 160 to the ionizer 134 when air is flowing from the air supply 154. In addition, the switch 162 is configured to disconnect the power supply 160 from the ionizer 134 when air is not flowing from the air supply 154. In one example, the valve 156 is closed by an appropriate control signal from an external controller when the system 100 operates in the second operational mode for testing a wafer 116, and the valve 156 is turned on continuously, or in pulsed fashion, during probe cleaning in the first operational mode.

The system 100 in FIG. 1 also includes a central controller 166. The controller 166 can include one or more processor components and associated electronic memory (not shown). In one example, the electronic memory of the controller 166 stores processor executable program instructions to implement automatic probe cleaning in the first operational mode, as well as wafer probe testing in the second operational mode, and translation of the apparatus 111 and 120 during transitions between the first and second operational modes using the respective positioners 118 and 124.

In the first support structure position of FIG. 1, the controller 166 and the cleaning arm positioner 124 position the nozzles 138, 128 and 130 proximate, but spaced from, one or more of the probe card needles 110 to provide touchless cleaning without contacting the needles 110 or the probe card 108. In the example of FIG. 1, the nozzles 138, 128 and 130 generally point to a single point or location of the bottom side of the probe card 108 and one or more of the needles 110. In this example, the support structure 126 in the first position supports the exhaust nozzle 138 to draw air and dislodged debris away from the probe needles 110 along a first direction substantially normal to a plane of the probe card 108 (e.g., downward along the −Z direction in FIG. 1). The support structure 126 in the first position supports the output nozzle 128 to direct the stream of ionized air toward the probe needles 110 along a second direction 131 at a non-zero angle 133 to the Z direction. In one example, the angle 133 is about 10 degrees or more and about 60 degrees or less. In the illustrated example, the second output nozzle 130 is supported on the support structure 126 to direct a second stream of ionized air toward the probe needles 110 along a third direction at a second non-zero angle to the first direction (e.g., about 10-60 degrees to the Z direction).

In the first operating mode shown in FIG. 1, the controller 166 facilitates automatic cleaning by automatically sending signals or commands to the positioners 118 and 124 to automatically clean the probe needles 110 and the probe card 108. In this mode, the controller sends suitable signals or commands to the chuck positioner 118 to position the chuck apparatus 111 in a first chuck position spaced away from the probe at assembly 101. In this mode, the controller 166 also sends suitable signals or commands to the cleaning arm positioner 124 to position the support structure 126 in the first support structure position to locate the output nozzles 128, 130 to direct streams of ionized air toward the probe needles 110 and the probe card 108, and to locate the exhaust nozzle 138 to draw air and dislodged debris away from the probe needles 110 of the probe card 108. In one example, the support structure 126 supports the exhaust nozzle 138 and the output nozzle 128 in the first position spaced from the probe needles 110 by a distance 168 of 5 mm or more and 50 mm or less, as shown in FIG. 1. In specific implementations, the spacing distance 168 can be adjusted in accordance with a selected operating peak pressure of the directed ionized air in order to achieve a desired amount of debris removal while avoiding or mitigating damage to the needles 110.

In the second operational mode, the controller 166 sends suitable signals or commands to the positioners 118 and 124 to position the support structure 126 in a second support structure position spaced from the probe at assembly 101, and to position the chuck apparatus 111 in a second chuck position to contact the wafer 116 with the probe needles 110, discussed further below in connection with FIG. 3. In the second mode, the controller 166 in one example exchanges data and/or messages with the electronic test circuit 105 to control wafer probe testing to implement one or more test routines or programs, such as short circuit detection, open circuit detection, operational circuit testing, etc.

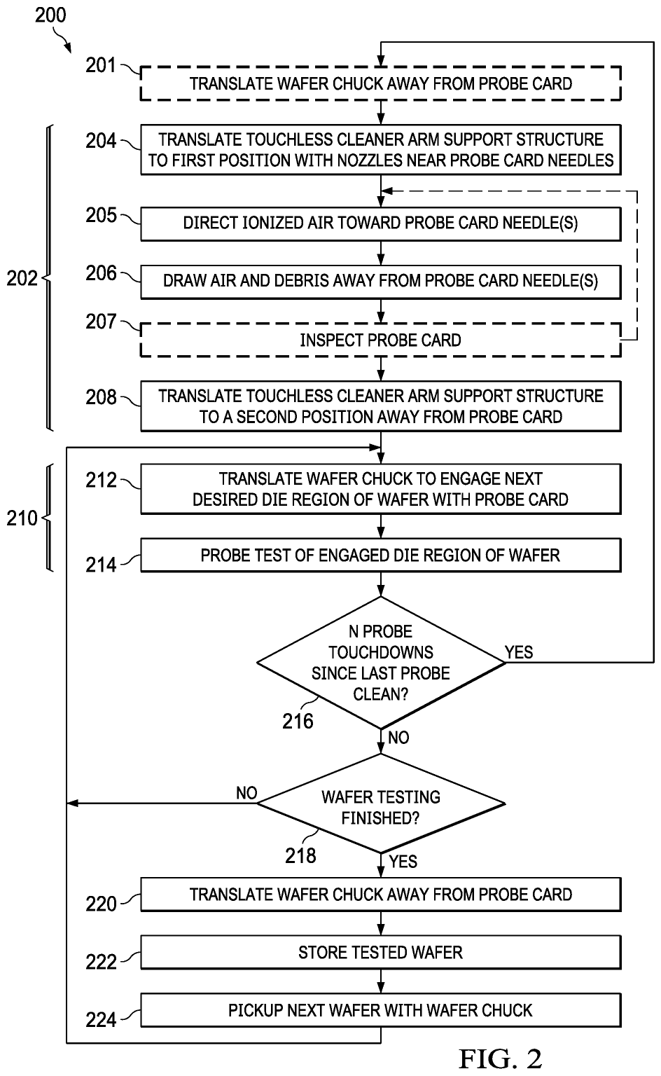

Referring also to FIGS. 2 and 3, FIG. 2 shows a method 200 for automatic probe cleaning and wafer testing. FIG. 3 shows the example system 100 in the second operational mode for wafer probe testing. The method 200 is described below in connection with operation of the system 100 of FIGS. 1 and 3. In other examples, the method 200 can be implemented in different systems (not shown).

The example method 200 begins at 201 in FIG. 2, where the wafer chuck apparatus 111 is translated by the controller 166 and the chuck positioner 118 away from the probe card 108 and away from the probe head assembly 101. At 202 in FIG. 2, the method 200 further includes probe card and probe needle cleaning, with the system 100 and the controller 166 in the first operational mode. At 204, the controller 166 uses the cleaning arm positioner 124 to translate the support structure 126 to the first support structure position (FIG. 1) with the nozzles 128, 130 and 138 proximate the probe card needles 110. Thereafter, the probe card 108 and the needles 110, or portions thereof, are cleaned at 205 and 206 in FIG. 2. At 205, the method 200 includes directing a stream of ionized air through the output nozzle 128 and the second output nozzle 130 toward the probe card 108 to dislodge debris from the probe needles 110. Concurrently at 206, the method 200 includes drawing air and the dislodged debris away from the probe card 108 through the exhaust nozzle 138 while directing the stream of ionized air toward the probe card 108.

As shown in FIG. 1, the coverage area of the cleaning assembly nozzles 128, 130 and 138 may be less than the spatial extent of the probe card 108 and the probe card needles 110. In one example, the controller 166 actuates the positioner apparatus 124 in order to perform X-Y raster type scanning or other translation to perform cleaning of the probe card 108 and the probe card needles 110 one portion at a time. In one example, the support structure 124 is located at a specific X-Y position, and remains in that position during directed ionized air cleaning for a programmed or programmable time. Thereafter, the controller 166 causes the positioner apparatus 124 to translate the support structure 126 to a second different X-Y position to clean a second portion of the probe card 108 and the needles 110. In one possible implementation, the probe card 108 and/or the needles 110 can be inspected at 207 after a portion thereof have been cleaned at 205 and 206. The inspection, where performed, can be visual or can be done through automated inspection equipment, such as cameras, etc. In another example, the inspection at 207 is omitted.

The portion-by-portion cleaning continues at 205 and 206 until the probe card 108 and the needles 110 have been cleaned using directed ionized air and vacuum withdrawal of dislodged debris. This is shown in the method 200 as directing ionized air toward the probe card needles 110 at 205, and drawing air and debris away from the probe card needles at 206. As an example, the vacuum pump 140 and the ionizer 134 are operated generally continuously for concurrent performance of the operations at 205 and 206, although not a strict requirement for all possible implementations. In addition, in one example, the controller 166 selectively opens and closes the valve 156 during the cleaning operations at 205 and 206 in order to direct pulsed ionized air streams toward the currently selected portion of the probe card 108 and the needles 110. In one example, the controller 166 alternates between continuous and pulsed air cleaning during the cleaning at 205 and 206.

Once the probe card 108 and needles 110 have been cleaned, the method 200 continues at 208 in FIG. 2, where the controller 166 translates the cleaner arm support structure 126 to the second support structure position spaced away from the probe card 108 and the probe head assembly 101. FIG. 3 shows this positioning of the cleaning apparatus 120 spaced apart from the probe head assembly 101. The method 200 thereafter includes wafer probe testing at 210 of one or more portions of a tested wafer 116. At 212 in FIG. 2, the controller 166 uses the chuck positioner apparatus 118 to translate the chuck apparatus 111 with an installed wafer 116 proximate the probe card 108 to contact the wafer 116 with the probe needles 110. FIG. 3 shows one example, with the chuck apparatus 111 positioned to engage the probe needles 110 with conductive features of a portion of the tested wafer 116. At 214 in FIG. 2, the method 200 further includes probe testing of the engaged die region of the wafer 116. The controller 166 in one example controls operation of the electronic test circuit 105 in implementing the probe testing at 214 to test the wafer 116 while the probe needles 110 are in contact with the wafer 116. In another example, the electronic test circuit 105 performs the desired wafer probe testing at 214 independent of the controller 166.

Once the engaged die region has been tested at 214, the method 200 continues at 216 in FIG. 2. In this example, a determination is made at 216 as to whether an integer number N probe touchdowns have occurred since the last probe cleaning operation at 202. As used herein, a probe touchdown is a single engagement of the probe needles 110 with a selected die portion of a tested wafer 116 installed in the carrier 114 of the chuck apparatus 111. The controller 166 can be programmed to implement a predetermined integer number N touchdowns between probe cleaning operations, or the number N can be dynamically adjusted in other implementations. In one example, N is approximately 75, although any suitable value for N can be used. If N touchdowns have occurred since the last probe cleaning operation (YES at 216), the method 200 returns to translate the wafer chuck away from the probe card at 201, reposition the support structure 126 proximate the probe card 108 at 204, and re-clean the probe card and needles 110 by again directing streams of ionized air toward the probe card 108 at 205 while drawing air and dislodged debris away from the probe card 108 at 206, before returning to wafer probe testing at 210.

If fewer than N touchdowns have occurred since the last probe cleaning operation (NO at 216), the controller 166 determines at 218 whether the wafer probe testing of the currently installed wafer 116 has been completed. If not (NO at 218), the method 200 returns to translate the wafer chuck to engage the next desire die region of the wafer 116 with the probe card 108 and the probe needles 110 as described above. This is followed by probe testing at 214 of the engaged die region of the wafer 116. Once the wafer testing is completed (YES at 218), the controller translates the wafer chuck apparatus 111 away from the probe card 108 and the probe head assembly 101 at 220 in FIG. 2, and stores the tested wafer at 222. The process in one example continues thereafter with the chuck apparatus 111 proceeding to pick up a next wafer to be tested at 224 with the wafer chuck apparatus 111, after which the process 200 returns for testing of the first selected die portion of the newly engaged wafer 116 at 210 as described above.

The example cleaning apparatus, systems, and cleaning methods advantageously provide touchless wafer probe card and needle cleaning to remove built up debris from the needles 110 and the probe card 108. In practice, the described cleaning apparatus and techniques can achieve debris removal not possible with conventional scrubbing pads and/or brushes. Furthermore, the described cleaning apparatus 120 and the method 200 avoid the extra scraping of prior probe cleaning techniques and systems, thereby extending the useful life of a given probe card 108 and probe needles 110. Furthermore, specific examples of the described apparatus 120 and method 200 provide pressure regulation to avoid undue mechanical strain on the probe needles 110, with continuous directed ionized air streams and/or pulsed ionized air streams. Furthermore, the use of ionized cleaning air facilitates discharging of the cleaned probe card 108 and the probe needles 110, while enhancing debris removal by discharging magnetically attached debris for removal via the vacuum pump 140. The example apparatus and techniques can be used with any type or form of probe card 108 and probe needles 110, including straight needles 110, cantilevered probe needles, etc. The example apparatus and techniques can be used in association with probe cards 108 and probe needles 110 used for wafer probe testing of any surface features of a tested wafer, including without limitation probing of copper or aluminum pillar structures, copper or aluminum conductive pads on the surface of a wafer 116, solder bumps formed on the surface of the tested wafer 116, etc.

In one example implementation, compressed dry air (CDA) from a factory air supply is used to deliver air to the valve 156, with the pressure regulator 150 operating to control the peak air pressure to 30 PSI or less to avoid bending or otherwise damaging the needles 110. The controller 166 can implement sustained and/or pulsed air cleaning in different limitations, for example, according to a cleaning program or recipe. In one non-limiting example, pulsed cleaning at a peak pressure of 20 PSI provides adequate cleaning for significant debris removal for cantilevered probe needles 110, with a 5 mm minimum clearance distance 168. In another example, 20 PSI pulsed cleaning was used for straight needles 110, resulting in removal of most debris. In another example, 10 PSI sustained and pulsed cleaning leaves some particles remaining for cantilevered needles 110, whereas 20 PSI sustained cleaning provides significant debris removal. In practice, the apparatus and techniques of the present disclosure can be tailored to a given cleaning application by selection of pulsed and/or sustained ionized air stream delivery, adjustment of the spacing distance 168 between the nozzles 128, 130, 138 and the probe needles 110, as well as adjustment of the ionized air delivery needle angle 133, the airstream peak pressure, and the duration of testing. In various implementations, the described techniques and apparatus provide improved cleaning compared with scrubbing pads and/or brushes, with significantly reduced wear on the cleaned probe card 108 and probe needles 110 due to the touchless cleaning.

Modifications are possible in the described embodiments, and other embodiments are possible, within the scope of the claims.

The following is claimed:

1. An apparatus, comprising:
a vacuum pump with an output connected to draw air through an exhaust nozzle;
an ionizer with an output connected to direct a stream of ionized air through an output nozzle; and
a support structure that supports the exhaust nozzle and the output nozzle in a first position proximate a probe needle of a probe card.

2. The apparatus of claim 1, wherein the support structure is movable between the first position and a second position that allows the probe needle to contact a wafer for testing.

3. The apparatus of claim 2, further comprising a controller configured to automatically position the support structure in the first position to locate the output nozzle to direct the stream of ionized air toward the probe needle of the probe card, and to locate the exhaust nozzle to draw air and dislodged debris away from the probe needle of the probe card.

4. The apparatus of claim 3, further comprising a valve connected between an air supply and the ionizer, wherein the controller is configured to operate the valve to cause the ionizer to direct the stream of ionized air through the output nozzle as a pulsed stream of ionized air toward the probe needle when the support structure is in the first position.

5. The apparatus of claim 1,
wherein the support structure in the first position supports the exhaust nozzle to draw air and dislodged debris away from the probe needle along a first direction substantially normal to a plane of the probe card; and
wherein the support structure in the first position supports the output nozzle to direct the stream of ionized air toward the probe needle along a second direction at a non-zero angle to the first direction.

6. The apparatus of claim 5, further comprising a second output nozzle connected to the output of the ionizer and supported on the support structure to direct a second stream of ionized air toward the probe needle along a third direction at a second non-zero angle to the first direction.

7. The apparatus of claim 1, further comprising a pressure regulator connected between an air supply and the ionizer, the pressure regulator configured to control a peak pressure of the stream of ionized air directed toward the probe needle to be 5 pounds per square inch (PSI) or more and 30 PSI or less.

8. The apparatus of claim 7, further comprising:
a controller configured to automatically position the support structure in the first position to locate the output nozzle to direct the stream of ionized air toward the probe needle of the probe card, and to locate the exhaust nozzle to draw air and dislodged debris away from the probe needle of the probe card; and
a valve connected between an air supply and the ionizer and configured to operate the valve to cause the ionizer to direct the stream of ionized air through the output nozzle as a pulsed stream of ionized air toward the probe needle when the support structure is in the first position.

9. The apparatus of claim 7, wherein the controller is configured to automatically position the support structure in the first position to locate the exhaust nozzle and the output nozzle spaced from the probe needle by a distance of 5 mm or more and 50 mm or less.

10. The apparatus of claim 1, wherein the support structure supports the exhaust nozzle and the output nozzle in the first position spaced from the probe needle by a distance of 5 mm or more and 50 mm or less.

11. The apparatus of claim 1, further comprising a flow switch connected between an air supply and the ionizer, the flow switch including a switch configured to connect a power supply to the ionizer when air is flowing from an air supply, and to disconnect the power supply from the ionizer when air is not flowing from the air supply.

12. A system, comprising:
a probe head assembly, including a probe card with a probe needle;
a chuck apparatus configured to support a wafer, the chuck apparatus movable between a first chuck position that allows the probe needle to be cleaned, and a second chuck position that contacts the wafer with the probe needle;
a cleaning apparatus, comprising:
a vacuum pump with an output connected to draw air through an exhaust nozzle,
an ionizer with an output connected to direct a stream of ionized air through an output nozzle, and
a support structure that supports the exhaust nozzle and the output nozzle in a first support structure position proximate a probe needle of a probe card, the support structure movable between the first support structure position and a second support structure position that allows the probe needle to contact a wafer for testing; and
a controller configured to operate in a first mode to automatically clean the probe needle and a separate second mode to automatically test the wafer, the controller configured to:
in the first mode, position the chuck apparatus in the first chuck position, and position the support structure in the first support structure position to locate the output nozzle to direct the stream of ionized air toward the probe needle, and to locate the exhaust nozzle to draw air and dislodged debris away from the probe needle of the probe card, and
in the second mode, position the support structure in the second support structure position, and position the chuck apparatus in the second chuck position to contact the wafer with the probe needle.

13. The system of claim 12,
wherein the cleaning apparatus further includes a valve connected between an air supply and the ionizer, and
wherein the controller is configured to, in the first mode, operate the valve to cause the ionizer to direct the stream of ionized air through the output nozzle as a pulsed stream of ionized air toward the probe needle when the support structure is in the first support structure position.

14. The system of claim 12,
wherein the support structure in the first support structure position supports the exhaust nozzle to draw air and dislodged debris away from the probe needle along a first direction substantially normal to a plane of the probe card; and
wherein the support structure in the first support structure position supports the output nozzle to direct the stream of ionized air toward the probe needle along a second direction at a non-zero angle to the first direction.

15. The system of claim 14, wherein the cleaning apparatus further includes a second output nozzle connected to the output of the ionizer and supported on the support structure to direct a second stream of ionized air toward the probe needle along a third direction at a second non-zero angle to the first direction.

16. The system of claim 12, wherein the cleaning apparatus further includes a pressure regulator connected between an air supply and the ionizer, the pressure regulator configured to control a peak pressure of the stream of ionized air directed toward the probe needle to be 5 pounds per square inch (PSI) or more and 30 PSI or less.

17. The system of claim 12, wherein the support structure supports the exhaust nozzle and the output nozzle in the first support structure position spaced from the probe needle by a distance of 5 mm or more and 50 mm or less.

18. The system of claim 12, wherein the cleaning apparatus further includes a flow switch connected between an air supply and the ionizer, the flow switch including a switch configured to connect a power supply to the ionizer when air is flowing from an air supply, and to disconnect the power supply from the ionizer when air is not flowing from the air supply.

19. A method, comprising:
positioning a support structure with exhaust and output nozzles proximate a probe needle of a probe card;
directing a stream of ionized air through the output nozzle toward the probe card to dislodge debris from the probe needle of the probe card; and
drawing air and the dislodged debris away from the probe card through the exhaust nozzle while directing the stream of ionized air toward the probe card.

20. The method of claim 19, further comprising:
translating the support structure away from the probe card;
translating a chuck apparatus with an installed wafer proximate the probe card to contact the wafer with the probe needle;
testing the wafer while the probe needle is in contact with the wafer; and
after testing the wafer:
translating the chuck apparatus away from the probe card,
repositioning the support structure proximate the probe card; and
re-cleaning the probe card, including again directing the stream of ionized air toward the probe card while drawing air and the dislodged debris away from the probe card.
